(19) United States
(12) Patent Application Publication
(10) Pub. No.: US 2026/0180529 A1
(43) Pub. Date: Jun. 25, 2026

(54) COMMON SOURCE AND SOURCE FOLLOWER BUFFER TO INTERFACE UP-CONVERTER AND DRIVER AMPLIFIER

(71) Applicant: QUALCOMM Incorporated, San Diego, CA (US)

(72) Inventors: Osama ELHADIDY, San Diego, CA (US); Ibrahim Ramez CHAMAS, Carlsbad, CA (US); Bhushan Shanti ASURI, San Diego, CA (US)

(21) Appl. No.: 18/989,894

(22) Filed: Dec. 20, 2024

(51) Int. Cl. H03F 3/45; H03F 3/50; H04B 1/04; H04B 1/16

(52) U.S. Cl. CPC H03F 3/45183; H03F 3/505; H04B 1/04; H04B 1/1615; H03F 2200/294; H03F 2200/451; H04B 2001/0408

(57) ABSTRACT

In some aspects, a buffer may interface an up-converter and a driver amplifier in a wireless transmitter. The buffer may comprise one or more branches that each include a first p-channel metal-oxide-semiconductor (PMOS) transistor having a source coupled to an output node, a gate coupled to an input voltage and to a first bias voltage, and a drain coupled to ground and a second PMOS transistor having a source coupled to a supply voltage, a gate coupled to an input voltage and to a second bias voltage, and a drain coupled to the output node. Accordingly, the buffer may include one or more PMOS transistor pairs in a common source and source follower configuration to provide low swing at an output from the up-converter, higher swing at an input to the driver amplifier, filter common mode noise and/or harmonics, and/or reduce undesired amplitude-to-phase modulation (AM/PM) effects.

### FIELD OF THE DISCLOSURE

Aspects of the present disclosure generally relate to wireless transceivers, and to an interface between an up-converter and a driver amplifier in a wireless transmitter.

### BACKGROUND

Wireless devices often include a transceiver to communicate with another wireless device over a wireless link. For example, a wireless transceiver is an integrated device that combines wireless transmission and wireless reception functionalities. The transmit chain in a transceiver typically includes a baseband signal processor that modulates a baseband signal, and a mixer that up-converts the modulated signal to prepare the baseband signal for radio frequency (RF) transmission. The up-converted signal is then amplified by a power amplifier to increase a strength of the signal before the signal is sent to an antenna that converts the signal into electromagnetic waves that propagate through the air to an intended receiver. On the receive side, the antenna captures and converts incoming electromagnetic waves into electrical signals that are provided to a receive chain. The receive chain typically includes a low-noise amplifier (LNA) that amplifies the received signal to enhance signal strength and reduce noise. The amplified signal is then down-converted to a lower frequency by a mixer, and subject to further amplification and demodulation by a baseband processor to retrieve the original data.

### SUMMARY

In some aspects, a circuit includes an up-converter mixer configured with differential outputs; a driver amplifier including a gain transistor; and a buffer to interface the up-converter mixer to the driver amplifier, wherein the buffer comprises a stacked pair of transistors coupled between a supply voltage and a ground, wherein a source of a first transistor of the stacked pair of transistors is connected to a drain of a second transistor of the stacked pair of transistors, wherein the drain and the source are coupled to the gain transistor, wherein a gate of each of the stacked pair of transistors is coupled to a respective output of the differential outputs, and wherein the stacked pair of transistors are complementary to the gain transistor.

In some aspects, a buffer includes a plurality of branches, wherein the plurality of branches each include: a first p-channel metal-oxide-semiconductor (PMOS) transistor having a source coupled to an output node, a gate coupled to an input voltage and to a first bias voltage, and a drain coupled to ground; and a second PMOS transistor having a sources coupled to a supply voltage, a gates coupled to an input voltage and to a second bias voltage, and a drain coupled to the output node.

In some aspects, a transmission circuit includes a mixer; a plurality of segments each configured to be selectively deactivated, wherein each segment of the plurality of segments includes: a driver amplifier (DA); and a buffer to interface the mixer to the DA in the segment, wherein each buffer comprises: a pair of PMOS transistors arranged in a common source and source follower configuration.

Aspects generally include an apparatus, a method, a system, a wireless communication device, a transceiver, a transmitter, a buffer, a common source and source follower, an amplifier, and/or a circuit, as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example environment with an electronic device that includes a wireless interface device, in accordance with the present disclosure.

FIG. 2 is a diagram illustrating an example transceiver, in accordance with the present disclosure.

FIG. 3 is a diagram illustrating an example transmit signal path that includes an interface circuit coupling an up-converter (UPC) to a driver amplifier (DA), and various example designs for the interface circuit coupling the UPC to the DA, in accordance with the present disclosure.

FIG. 4 is a diagram illustrating an example p-channel metal-oxide-semiconductor (PMOS)-PMOS (PP) buffer and associated bias circuit, in accordance with the present disclosure.

FIG. 5 is a diagram illustrating an example architecture using a buffer that includes a PP (common source and source follower) buffer and associated bias circuit to provide a UPC-DA interface, and a high-pass filter for noise filtering at an output from the buffer, in accordance with the present disclosure.

FIG. 6 is a diagram illustrating examples of amplifier circuits, in accordance with the present disclosure.

FIGS. 7-8 are diagrams illustrating example architectures that include one or more DA and PP buffer segments to reduce talk-time power consumption in a wireless transceiver, in accordance with the present disclosure.

FIG. 9 is a diagram illustrating an example beamforming architecture, in accordance with the present disclosure.

### DETAILED DESCRIPTION

Various aspects of the present disclosure are described hereinafter with reference to the accompanying drawings. However, aspects of the present disclosure may be embodied in many different forms and is not to be construed as limited to any specific aspect illustrated by or described with reference to an accompanying drawing or otherwise presented in this disclosure. Rather, these aspects are provided so that this disclosure will be thorough and complete, and will fully convey the scope of the disclosure to those skilled in the art. One skilled in the art may appreciate that the scope of the disclosure is intended to cover any aspect of the disclosure disclosed herein, whether implemented independently of or in combination with any other aspect of the disclosure. For example, an apparatus may be implemented or a method may be practiced using various combinations or quantities of the aspects set forth herein. In addition, the scope of the disclosure is intended to cover an apparatus having, or a method that is practiced using, other structures and/or functionalities in addition to or other than the structures and/or functionalities with which various aspects of the disclosure set forth herein may be practiced. Any aspect of the disclosure disclosed herein may be embodied by one or more elements of a claim.

In a wireless transmitter, various components may be implemented with a super-heterodyne architecture or a direct-conversion architecture to convert a baseband or intermediate frequency (IF) signal to a high-frequency radio frequency (RF) signal suitable for over-the-air transmission. More particularly, a super-heterodyne architecture generally includes various components that are configured to convert a signal from a baseband frequency to an RF in multiple stages (e.g., from the baseband frequency to an IF in a first stage, and then from the IF to the RF in a second stage), and a direct-conversion architecture includes various components configured to convert a signal from a baseband frequency to an RF in one stage. For example, in a typical transmit signal path, a digital-to-analog converter (DAC) may convert a digital baseband signal into an analog baseband signal that can then be processed in an analog domain. The DAC may provide the analog baseband signal to a baseband filter (BBF), and the BBF may filter the analog baseband signal to isolate or remove undesired frequency components. In some cases, the BBF may include or may be followed by a second pole filter, which may further filter the analog baseband signal (e.g., at a different frequency point than the BBF) to better suppress unwanted frequencies.

After the analog baseband signal has been suitably filtered, the filtered baseband signal may be provided to an up-converter (UPC) configured to convert the analog baseband signal to an RF signal suitable for wireless transmission. For example, the UPC may include one or more mixers that mix the analog baseband signal with one or more oscillating signals generated by one or more local oscillators (LOs) to shift the analog signal from the baseband frequency to the RF (e.g., directly, or via an IF). The RF signal is then provided to a driver amplifier (DA) that may provide a gain. The DA may produce a desired output power level for the RF signal or an output of the DA may be coupled to a power amplifier (PA) to provide the desired output power level for the RF signal. In some examples, the DA is the first stage of the PA. The amplified RF signal may optionally be provided to an electromagnetic (EM) circuit and/or other components to provide filtering, amplification, and/or other suitable functions to condition the RF signal for wireless transmission, and the conditioned RF signal is provided to one or more output switches and/or attenuators for transmission via one or more antennas.

As described herein, one challenge in a wireless transmitter design relates to an interface between the UPC and the DA. For example, in some cases, the UPC may be coupled to the DA using a through interface, which is essentially one or more wires that couple the UPC output to the DA input. Although the through interface has a wide frequency range and consumes negligible area, the through interface provides no gain, which can have a significant impact on overall performance in the wireless transmitter. For example, the UPC is typically subject to certain requirements on an output swing (e.g., a difference between a maximum and minimum output voltage) that determines a linearity associated with the UPC, and the DA has certain requirements on an input swing (e.g., a difference between a maximum and minimum input voltage) that determines a current consumption, power efficiency, and/or linearity associated with the DA. For example, the linearity associated with the UPC (which may also be referred to as a mixer, a UPC mixer, a UPC passive mixer (in some configurations), or the like) generally improves when the output swing is lower, whereby there may be limits on the output swing from the UPC. On the other hand, a larger input swing at the DA results in the DA having an improved power efficiency (e.g., a larger DA that consumes more power may be needed when the input swing is low, and a low swing also increases a load on a previous circuit driving the DA). Accordingly, because the UPC performance improves with a low swing and the DA performance improves with a high swing, the through interface poses challenges because the lack of gain results in the UPC and DA having to operate at the same swing. In addition, the through interface does not provide any low frequency noise, common mode noise, or RF harmonics (e.g., 3LO) filtering. Due to these challenges, the through interface is typically limited to low frequencies or low bands only.

Alternatively, in some cases, an EM interface may be provided between the UPC and the DA. For example, an EM interface may include a transformer with a primary inductor and a secondary inductor, which may provide a gain to allow a relatively low swing at the UPC output and a relatively higher swing at the DA input, which may improve the linearity associated with the UPC and improve the power efficiency, linearity, and/or noise associated with the DA. For example, an inductance of the primary inductor and/or an inductance of the secondary inductor may be optimized to control a gain provided by the EM interface. In addition, the EM interface may provide low frequency noise, common mode noise, and RF harmonics (e.g., 3LO or 5LO) filtering. Accordingly, the EM interface is often used for any transmit signal paths other than a low band (e.g., mid-frequency bands, high-frequency bands, unlicensed frequency bands, or the like). However, the EM interface may have a narrow frequency range, and occupies significant area. For example, in a transceiver that supports wireless communication at different frequencies, such as low-frequency bands, mid-frequency bands, high-frequency bands, and/or unlicensed frequency bands, the transceiver may include an EM interface in each signal path except a low band signal path. The EM interfaces in each signal path also create a need for separate mixers and LOs in each signal path, which further increases the area occupied by the wireless transmitter.

Some aspects described herein relate to an wideband circuit that interfaces a UPC mixer to a DA in a wireless transmitter to improve frequency range and reduce an area associated with a transmit signal path, which may further be accomplished while providing high performance and reducing current consumption at talk time (e.g., a time when the wireless transmitter is processing signals to be transmitted). For example, in some aspects, the circuit may be implemented as a buffer that includes one or more transistor pairs in a common source and source follower configuration. For example, as described herein, a buffer with a source follower configuration may help to isolate a DA input capacitance from the UPC, which may improve a UPC load impedance. Furthermore, implementing a common source configuration with the source follower configuration may provide a gain to enable a low swing at the UPC output and a higher swing at the DA input, enable common mode noise filtering, and enable harmonic filtering. Furthermore, implementing the common source and source follower buffer with transistors that complement the transistor(s) implemented in the DA may provide amplitude-to-phase modulation (AM/PM) performance comparable to an EM interface or a standalone source follower buffer. For example, in cases where the DA is implemented using n-channel metal-oxide-semiconductor (NMOS) transistors, the common source and source follower buffer may be implemented with p-channel metal-oxide-semiconductor (PMOS) transistors to complement the NMOS transistor(s) implemented in the DA. Alternatively, in cases where the DA is implemented using PMOS transistors, the common source and source follower buffer may be implemented with NMOS transistors to complement the PMOS transistor(s) implemented in the DA. In this way, the interface between the UPC and the DA in a wireless transmitter may be implemented using a common source and source follower buffer, which may improve isolation and reduce the overall transmitter area relative to a design where an EM interface is used between the UPC and the DA in a transmit signal path. Furthermore, the buffer with the common source and source follower configuration may allow for band combining, which may further reduce the overall transmitter area, limit additional noise to a manageable level, and/or enable reduced power consumption at talk time. Thus, while buffers described herein may not reduce circuit area as compared to a through interface (e.g., as used in a low band path or configuration), such buffers may provide other benefits as described above and thus may advantageously be implemented in certain low band transmission paths or configurations.

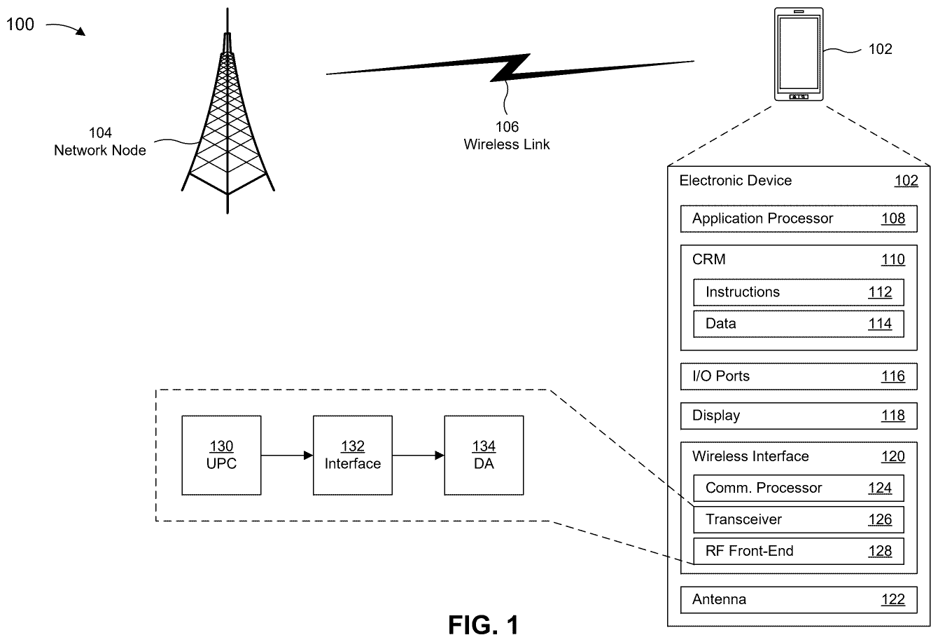

FIG. 1 is a diagram illustrating an example environment 100 with an electronic device 102 that includes a wireless interface device 120, in accordance with the present disclosure. In some aspects, as described in further detail elsewhere herein, the wireless interface device 120 may include a UPC 130, a DA 134, and an interface circuit 132 to couple an output from the UPC 130 to an input to the DA 134.

In the example environment 100, the electronic device 102 may communicate with a network node 104 through a wireless link 106. For example, the network node 104 may include one or more devices, components, or systems that enable communication between the electronic device 102 and one or more devices, components, or systems in the environment 100. The network node 104 may be, may include, or may also be referred to as a base station, a New Radio (NR) network node, a 5G network node, a 6G network node, a Node B, an eNB, a gNB, an access point (AP), a transmission reception point (TRP), a mobility element, a core network entity, a network element, a network equipment, a radio unit (RU), a distributed unit (DU), a central unit (CU), and/or another suitable device that supports wireless communication.

In some aspects, the electronic device 102 may be any suitable computing device or other electronic device. For example, the electronic device 102 may be a smartphone, a cellular base station, a broadband router, an AP, a cellular or mobile phone, a user equipment (UE), a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, a fitness management device, a wearable device such as smart glasses or a smartwatch, a wireless power device (transmitter or receiver), a medical device, or the like.

The network node 104 may communicate with the electronic device 102 via the wireless link 106, which may be implemented as any suitable wireless link that carries a wireless communication signal. For example, the wireless link 106 may be implemented in a wireless network, which may include a cellular network, a public land mobile network (PLMN), a wireless local area network (WLAN), a wide area network (WAN), a metropolitan area network (MAN), a telephone network (e.g., the Public Switched Telephone Network (PSTN)), a private network, an ad hoc network, an intranet, a wireless personal area network (WPAN), and/or a combination of these or other networks. Although depicted as a base station tower in a cellular radio access network, the network node 104 may represent or be implemented as another device, such as a satellite, a terrestrial broadcast tower, an AP, a peer-to-peer device, a mesh network node, another electronic device as described above generally, or the like. Furthermore, although the electronic device 102 is depicted as communicating with the network node 104 via the wireless link 106, the electronic device 102 may communicate with the network node 104 or another device via a wired and/or wireless connection.

The wireless link 106 may include a downlink for communicating data or control information from the network node 104 to the electronic device 102, an uplink for communicating data or control information from the electronic device 102 to the network node 104, a sidelink for communicating data or control information from the electronic device 102 to the network node 104 or vice versa, or any suitable combination thereof. The wireless link 106 may be implemented using any suitable communication protocol or standard, such as a 3rd Generation Partnership Project Long-Term Evolution (3GPP) standard, such as a 4th Generation (4G), a 5th Generation (5G), a 6th Generation (6G), or another wireless communication standard, an Institute of Electrical and Electronics Engineers (IEEE) 802.11 or IEEE 802.16 standard, a Bluetooth standard, or the like. In some aspects, the wireless link 106 may wirelessly provide power instead of or in addition to communication signaling, and the electronic device 102 or the network node 104 may be a power source or a power sink.

As shown in FIG. 1, the electronic device 102 may include at least one application processor 108 and at least one computer-readable storage medium 110. The application processor 108 may include any suitable processor, such as a central processing unit (CPU) or a multicore or graphics processor, configured to execute processor-executable instructions (e.g., code) stored by the computer-readable storage medium 110. The computer-readable storage medium 110 may include any suitable data storage media, such as volatile memory (e.g., random-access memory (RAM)), non-volatile memory, optical media, magnetic media (e.g., disk or tape), or the like. The computer-readable storage medium 110 may be implemented to store instructions 112, data 114, or other suitable information, and therefore the computer-readable storage medium 110 does not include transitory propagating signals or carrier waves.

As shown in FIG. 1, the electronic device 102 may include one or more input/output (I/O) ports 116 and at least one display 118. The I/O ports 116 may enable data exchanges or interaction with other devices, networks, or users. The I/O ports 116 may include serial ports (e.g., universal serial bus (USB) ports), parallel ports, audio ports, infrared (IR) ports, camera or other sensor ports, or the like. The display 118 may include a display screen or a projection that may present one or more graphical images provided by the electronic device 102, such as a user interface associated with an operating system, program, or application. Additionally, or alternatively, the display 118 may be implemented as a display port or a virtual interface through which graphical content of the electronic device 102 is communicated or presented.

As described herein, the electronic device 102 may include at least one wireless interface device 120 and at least one antenna 122, which may be coupled one to another. The wireless interface device 120 may provide connectivity to respective networks and peer devices via a wireless link, which may be configured in a manner that is similar to or different from the wireless link 106. Additionally, or alternatively, the electronic device 102 may include a wired interface device, such as an Ethernet or fiber optic transceiver for communicating over a wired local area network (LAN), an intranet, or the Internet. The wireless interface device 120 may facilitate communication over any suitable type of wireless network, such as a WLAN, a WPAN, a peer-to-peer (P2P) network, a mesh network, a cellular network, a wireless wide area network (WWAN), and/or a navigational network (e.g., a Global Navigation Satellite System (GNSS)). The electronic device 102 may communicate various data and control information bidirectionally with a cellular network via the network node 104 using the wireless interface device 120. However, the electronic device 102 may also or instead communicate directly with peer devices, an alternative wireless network, or the like using the wireless interface device 120.

As shown in FIG. 1, the wireless interface device 120 may include at least one communication processor 124, at least one transceiver 126, and optionally at least one radio-frequency front-end (RFFE) 128. The communication processor 124 may be coupled to the transceiver 126, and the transceiver 126 may be coupled to the antenna 122, optionally through the RFFE 128 in some configurations. The communication processor 124 can also be directly coupled to the RFFE 128. In some examples, the communication processor 124 is implemented in a chip (or system-on-chip (SoC)) separate from a chip in which the transceiver 126 is implemented. Further, the RFFE 128 may be implemented in one or more chips or modules separate from the communication processor 124 and/or the transceiver 126. The communication processor 124, the transceiver 126, and the RFFE 128 may process data information, control information, and/or signals associated with communicating information via the antenna 122.

The communication processor 124 may be implemented as part of an SoC, as a modem baseband processor, or as a baseband processor (BBP) that may realize a digital communication interface for data, voice, messaging, or other applications. The communication processor 124 may include a digital signal processor (DSP) or one or more signal-processing blocks (not shown) for encoding and modulating data for transmission and for demodulating and decoding received data. Additionally, or alternatively, the communication processor 124 may manage (e.g., control or configure) aspects or operation of the transceiver 126, the RFFE 128, and/or other components of the wireless interface device 120 to implement various communication protocols or communication techniques.

In some aspects, the application processor 108 and the communication processor 124 may be combined into one module or integrated circuit (IC), such as an SoC. The application processor 108 or the communication processor 124 may be operatively coupled to one or more other components, such as the computer-readable storage medium 110 or the display 118. The operative coupling may enable control over, or other interaction with, other components of the electronic device 102 by at least one processor. Additionally, the communication processor 124 may include a memory, such as the computer-readable storage medium, 110, to store data and processor-executable instructions (e.g., code). The various components illustrated in FIG. 1 and/or the other drawings using separate schematic blocks may be manufactured or packaged in different discrete manners. For example, one physical module may include components of the RFFE 128 and some components of the transceiver 126, and another physical module may combine the communication processor 124 with the remaining components of the transceiver 126. Further, the antenna 122 may be co-packaged with at least some components of the RFFE 128 or the transceiver 126.

The transceiver 126 may include circuitry and logic for filtering, amplification, channelization, and/or frequency translation. The frequency translation may include an up-conversion or a down-conversion of frequency that is performed in a single conversion operation (e.g., with a direct-conversion architecture) or through multiple conversion operations (e.g., with a super-heterodyne architecture) using one or more mixers (e.g., as implemented by or included in the UPC 130). Accordingly, the transceiver 126 may include one or more filters, switches, amplifiers, mixers, and/or other suitable components for routing and conditioning signals that are transmitted or received via the antenna 122. Although not explicitly shown in FIG. 1, the wireless interface device 120 can also include a DAC or an analog-to-digital converter (ADC) to convert between analog signals and digital signals. The DAC and/or the ADC can be implemented as part of the communication processor 124, as part of the transceiver 126, or separately from both.

In some aspects, the transceiver 126 may include one or more configurable components that may be controlled by the communication processor 124 to implement communications in various modes, with different frequency bands, or to comport with a particular wireless standard. The components or circuitry of the transceiver 126 can be implemented in any suitable fashion, such as with combined transceiver logic or separately as respective transmitter and receiver entities. In some cases, the transceiver 126 may be implemented with multiple or different sections to implement respective transmitting and receiving operations (e.g., to implement separate transmit and receive chains or paths). The transceiver 126 may also include logic to perform in-phase and quadrature (I/Q) operations, such as synthesis, phase correction, modulation, and/or demodulation, among other examples.

In some aspects, the RFFE 128 may generally include one or more filters, switches, amplifiers, phase shifters, and/or other suitable components for conditioning signals received via the antenna 122 and/or for conditioning signals to be transmitted via the antenna 122. In some aspects, the RFFE 128 may also include other RF sensors and components, such as a peak detector, a power meter, a gain control block, an antenna tuning circuit, a diplexer, a balun, or the like. In some aspects, the RFFE 128 may include one or more configurable components, such as a phase shifter or a mixer, that may be controlled by the communication processor 124 to implement communications in various modes, with different frequency bands, or using beamforming. The RFFE 128 may be coupled to the antenna 122, which may be implemented as at least one individual antenna, as at least one antenna array that includes multiple antenna elements, or as at least one antenna element of an antenna array. Accordingly, as used herein, the term “antenna” can refer to an individual antenna, an antenna array, or an antenna element of an antenna array.

As indicated above, FIG. 1 is provided as an example. Other examples may differ from what is described with regard to FIG. 1.

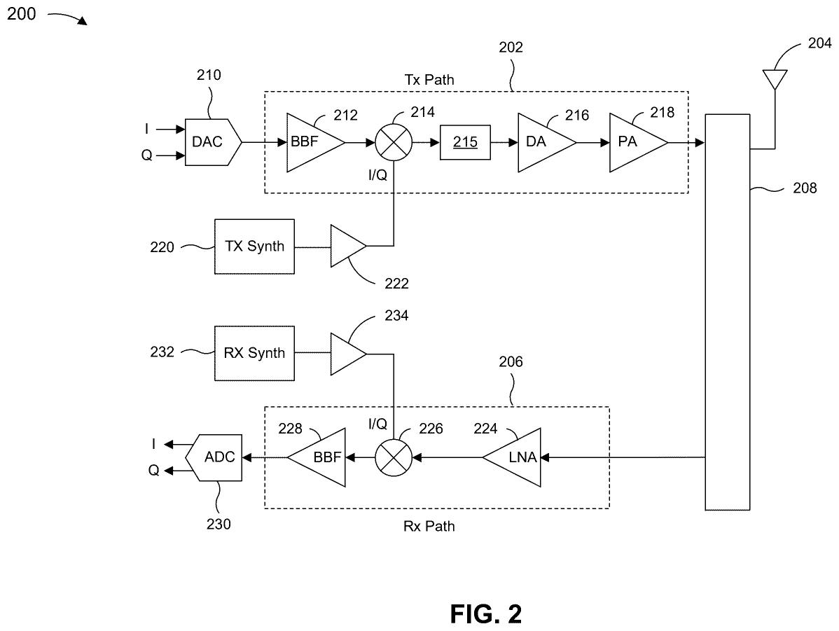

FIG. 2 is a diagram illustrating an example transceiver 200, in accordance with the present disclosure. The transceiver may be included in the wireless interface 120 shown in FIG. 1, for example in the transceiver 126 and/or the RFFE 128. As shown in FIG. 2, the transceiver 200 includes a transmit (Tx) path 202 (also known as a transmit chain) for transmitting signals via one or more antennas and a receive (Rx) path 206 (also known as a receive chain) for receiving signals via the antennas. When the Tx path 202 and the Rx path 206 share an antenna 204 (which may be an example of the antenna 122), the Tx path 202 and the Rx path 206 may be connected with the antenna 204 via an interface 208, which may include any of various suitable RF devices, such as a duplexer, a switch, and/or a diplexer, among other examples.

As shown in FIG. 2, a DAC 210 may receive in-phase (I) and quadrature (Q) baseband digital signals, which may be converted to baseband analog signals. As further shown in FIG. 2, the Tx path 202 may include a BBF 212, a mixer 214, a DA 216, an interface 215 coupling the mixer 214 to the DA 216, and a power amplifier (PA) 218. The BBF 212, the mixer 214, the interface 215, and the DA 216 may be included in a radio frequency integrated circuit (RFIC), while the PA 218 may be external to the RFIC in some configurations and included in the RFIC in other configurations. The BBF 212 may filter the baseband analog signals received from the DAC 210, and the mixer 214 may mix the filtered baseband signals with a transmit LO signal to convert the baseband signal to a target frequency (e.g., to up-convert from a baseband frequency to RF). The frequency conversion process may produce sum and difference frequencies of the LO frequency and the target frequency. The sum and difference frequencies are sometimes known as beat frequencies. The beat frequencies are typically in the RF range, such that the signals output by the mixer 214 are typically RF signals, which may be amplified by the DA 216 and/or by the PA 218 before transmission by the antenna 204. In some aspects, the mixer 214 may provide a symmetrical frequency response.

As further shown in FIG. 2, the Rx path 206 may include a low noise amplifier (LNA) 224, a mixer 226, and a BBF 228, among other examples. The LNA 224, the mixer 226, and the BBF 228 may be included in an RFIC, which may or may not be the same RFIC that includes the components of the Tx path 202. RF signals received via the antenna 204 may be amplified by the LNA 224, and the mixer 226 may mix the amplified RF signals with a receive LO signal to convert (e.g., down-convert) the RF signal to a different baseband frequency. The baseband signals output by the mixer 226 may be filtered by the BBF 228 before being converted by an ADC 230 to digital I/Q signals for digital signal processing.

In some aspects, the output of an LO should remain relatively stable in frequency. However, tuning the LO to different frequency typically entails using a variable-frequency oscillator, which may involve compromises between stability and tunability. In some cases, frequency synthesizers with a voltage-controlled oscillator (VCO) may be used to generate a stable, tunable LO with a particular tuning range. For example, as shown in FIG. 2, the transmit LO frequency may be produced by a Tx frequency synthesizer 220, which may be buffered or amplified by amplifier 222 before being mixed with the baseband signals in the mixer 214. Similarly, the receive LO frequency may be produced by an Rx frequency synthesizer 232, which may be buffered or amplified by amplifier 234 before being mixed with the RF signals in the mixer 226.

As indicated above, FIG. 2 is provided as an example. Other examples may differ from what is described with regard to FIG. 2.

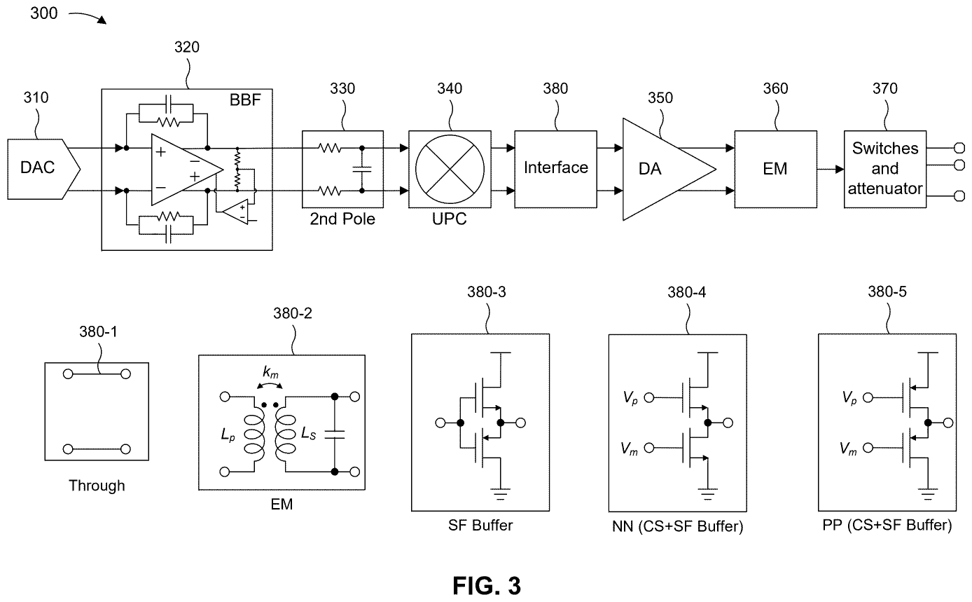

FIG. 3 is a diagram illustrating an example transmit signal path 300 that includes an interface 380 coupling a UPC 340 to a DA 350, and various example designs 380-1 through 380-5 for the interface circuit 380 coupling the UPC 340 to the DA 350, in accordance with the present disclosure. The transmit signal path 300 may be an example of the Tx path 202 or a portion thereof. As described herein, the transmit signal path 300 may be implemented in a wireless transmitter, and may include various components implemented with a super-heterodyne architecture or a direct-conversion architecture to convert a baseband or IF signal to a high-frequency RF signal suitable for over-the-air transmission. More particularly, a super-heterodyne architecture generally includes various components that are configured to convert a signal from a baseband frequency to an RF in multiple stages (e.g., from the baseband frequency to an IF in a first stage, and then from the IF to the RF in a second stage), and a direct-conversion architecture includes various components configured to convert a signal from a baseband frequency to an RF in one stage. For example, as shown in FIG. 3, the transmit signal path 300 includes a DAC 310 that may convert a digital baseband signal into an analog baseband signal that can then be processed in an analog domain. The DAC 310 may provide the analog baseband signal to a BBF 320, and the BBF 320 may filter the analog baseband signal to isolate or remove undesired frequency components. In some cases, the BBF 320 may include or may be followed by a second pole filter 330, which may further filter the analog baseband signal (e.g., at a different frequency point than the BBF 320) to better suppress unwanted frequencies.

After the analog baseband signal has been suitably filtered, the filtered baseband signal may be provided to the UPC 340, which may convert the analog baseband signal to an RF signal suitable for wireless transmission. For example, the UPC 340 may include one or more mixers configured to mix the analog baseband signal with one or more oscillating signals generated by one or more LOs to shift the analog signal from the baseband frequency to the RF (e.g., directly, or via an IF). The RF signal is then provided to the DA 350, which may provide a gain to obtain a desired output power level for the RF signal. The amplified RF signal may then be provided to an EM 360 circuit that may provide filtering, amplification, and/or other suitable functions to condition the RF signal for wireless transmission, and the conditioned RF signal is provided to one or more output switches and/or attenuators 370 for transmission via one or more antennas.

As described herein, one challenge in a wireless transmitter design relates to the interface 380 between the UPC 340 and the DA 350. For example, in some cases, the UPC 340 may be coupled to the DA 350 using a through interface 380-1, which is essentially one or more wires that couple the output from the UPC 340 to the input to the DA 350. Although the through interface 380-1 has a wide frequency range and consumes negligible area, the through interface 380-1 provides no gain, which can have a significant impact on overall performance in the transmit signal path 300. For example, the UPC 340 is typically subject to certain requirements on an output swing (e.g., a difference between a maximum and minimum output voltage) that determines a linearity associated with the UPC 340, and the DA 350 has certain requirements on an input swing (e.g., a difference between a maximum and minimum input voltage) that determines a current consumption, power efficiency, and/or linearity associated with the DA 350. For example, the linearity associated with the UPC 340 (which may also be referred to as a mixer, a UPC mixer, a UPC passive mixer (in some configurations), or the like) generally improves when the output swing is lower, whereby there may be limits on the output swing from the UPC 340. On the other hand, a larger input swing at the DA 350 results in the DA 350 having an improved power efficiency (e.g., a larger DA that consumes more power may be needed when the input swing is low, and a low swing also increases a load on a previous circuit driving the DA 350). Accordingly, because the performance of the UPC 340 improves with a low swing and the performance of the DA 350 improves with a high swing, the through interface 380-1 poses challenges because the lack of gain results in the UPC 340 and DA 350 having to operate at the same swing. In addition, the through interface 380-1 does not provide any low frequency, common mode, or RF (e.g., 3LO) filtering. Due to these challenges, the through interface 380-1 is typically limited to low frequencies or low bands only.

Alternatively, in some cases, an EM interface 380-2 may be provided between the UPC 340 and the DA 350. For example, as shown in FIG. 3, the EM interface 380-2 may include a transformer with a primary inductor and a secondary inductor, which may provide a gain to allow a relatively low swing at the output from the UPC 340 and a relatively higher swing at the input to the DA 350, which may improve the linearity associated with the UPC 340 and improve the power efficiency, linearity, and/or noise associated with the DA 350. For example, the EM interface 380-2 may provide a gain of

$$\frac{1}{{k}_{m}} \sqrt{{L}_{s} / {L}_{p}} ,$$

where Lₚ is a primary inductance of the transformer, Lₛ is a secondary inductance of the transformer, and kₘ is a coupling factor between the primary inductor and the secondary inductor. Accordingly, the inductance of the primary inductor and/or the inductance of the secondary inductor may be optimized to control the gain provided by the EM interface 380-2. In addition, the EM interface 380-2 may provide low frequency, common mode, and RF filtering (e.g., 3LO or 5LO filtering). Accordingly, the EM interface 380-2 may be used for any transmit signal paths other than a low band (e.g., mid-frequency bands, high-frequency bands, unlicensed frequency bands, or the like). However, the EM interface 380-2 may have a narrow frequency range, and occupies significant area. The EM interface 380-2 in a signal path also creates a need for separate mixers and LOs in the signal path, which further increases the area occupied by the devices or components that make up the signal path.

Accordingly, in some cases, the interface 380 between the UPC 340 and the DA 350 may be implemented using a source follower buffer 380-3, which includes a PMOS device and an NMOS device arranged in a source follower configuration. The source follower buffer 380-3 may improve a load impedance of the UPC 340 by isolating an input capacitance of the DA 350 from the UPC 340 (e.g., the UPC 340 may observe a much smaller load due to the isolation of the input capacitance of the DA 350). Furthermore, because the input capacitance of the DA 350 is isolated from the UPC 340, a size of the DA 350 may be optimized to provide a desired gain. In addition, the source follower buffer 380-3 has a wide frequency range, occupies a relatively small area (e.g., relative to the EM interface 380-2), and provides some 3LO filtering. However, the source follower buffer 380-3 provides a gain that is less than 1. Accordingly, because the gain is less than 1, the source follower buffer 380-3 may worsen the tradeoff between the linearity of the UPC 340 and the DA 350, because a swing at the input to the DA 350 will be lower than a swing at the output from the UPC 340 (e.g., whereas a higher swing at the input to the DA 350 is typically desired). Furthermore, the source follower buffer 380-3 introduces noise of

$$\frac{4 KT γ}{g m} ,$$

where K is Boltzmann's constant, T is a temperature in Kelvin, γ is a process-dependent noise constant and gm is an effective transconductance of the source follower buffer 380-3, and does not provide common mode noise filtering.

Accordingly, to improve upon the source follower buffer 380-3, the interface 380 between the UPC 340 and the DA 350 may be implemented using an NMOS-NMOS (NN) common source and source follower buffer 380-4, which may include a (stacked) pair of NMOS transistors arranged in a common source configuration and a source follower (also known as a common drain) configuration. For example, as shown, the NN common source and source follower buffer 380-4 includes a first NMOS transistor with a source coupled to an output node (e.g., the input to the DA 350), a gate coupled to a positive input voltage Vₚ (e.g., a first output from the UPC 340), and a drain coupled to a supply voltage. As further shown, the NN common source and source follower buffer 380-4 includes a second NMOS transistor with a source coupled to ground, a gate coupled to a negative input voltage Vₘ (e.g., a second output from the UPC 340), and a drain coupled to the output node (e.g., the input to the DA 350). In examples, the NN common source and source follower buffer 380-4 provides a gain that approaches 2 (e.g., about 4-5 decibels (dB), depending on design and power consumption), because the common source and the source follower each provide a gain that approaches 1 (e.g., resulting in a gain that approaches 2 when the gain of the common source and the source follower are added in a differential operation).

Furthermore, because the outputs from the NMOS transistors are subtracted and ideally cancel each other in a common mode operation, the NN common source and source follower buffer 380-4 provides a good common mode rejection (e.g., around 30 dB common mode noise filtering). In certain configurations in which the DA 350 and the NN common source and source follower buffer 380-4 are both implemented with NMOS transistors, AM/PM performance may be reduced, which degrades an adjacent channel leakage ratio (ACLR) and/or 3rd-order intermodulation distortion (IM3). On the other hand, in cases where the DA 350 is implemented with one or more PMOS transistors, the NN common source and source follower buffer 380-4 may provide very good AM/PM performance (e.g., comparable to the EM interface 380-2 or the source follower buffer 380-3).

Accordingly, in some aspects, the interface 380 between the UPC 340 and the DA 350 may be implemented using a PP common source and source follower buffer 380-5, which may include a (stacked) pair of PMOS transistors arranged in a common source configuration and a source follower configuration. For example, as shown, the PP common source and source follower buffer 380-5 is generally similar to the NN common source and source follower buffer 380-4, except that PMOS transistors are used to complement the NMOS transistors implemented in the DA 350. For example, as shown, the PP common source and source follower buffer 380-5 includes a first PMOS transistor with a source coupled to a supply voltage and a second PMOS transistor with a source coupled to an output node (e.g., corresponding the input to the DA 350). Furthermore, the first PMOS transistor includes a gate coupled to a positive input voltage Vₚ (e.g., a first output from the UPC 340), and the second PMOS transistor includes a gate coupled to a negative input voltage Vₘ (e.g., a second output from the UPC 340). In addition, as shown, the first PMOS transistor includes a drain coupled to the output node, and the second PMOS transistor includes a drain coupled to ground. In this way, the PP common source and source follower buffer 380-5 has similar advantages as the NN common source and source follower buffer 380-4, including a gain that may approach 2, common mode noise filtering, harmonic RF filtering, a wide frequency range, and a relatively small area. Furthermore, when the PMOS transistors complement the AM/PM performance of an NMOS transistor(s) implemented in the DA 350, the PP common source and source follower buffer 380-5 provides very good AM/PM performance (e.g., comparable to the EM interface 380-2 or the source follower buffer 380-3), which results in improved ACLR and IM3 performance.

As indicated above, FIG. 3 is provided as an example. Other examples may differ from what is described with regard to FIG. 3.

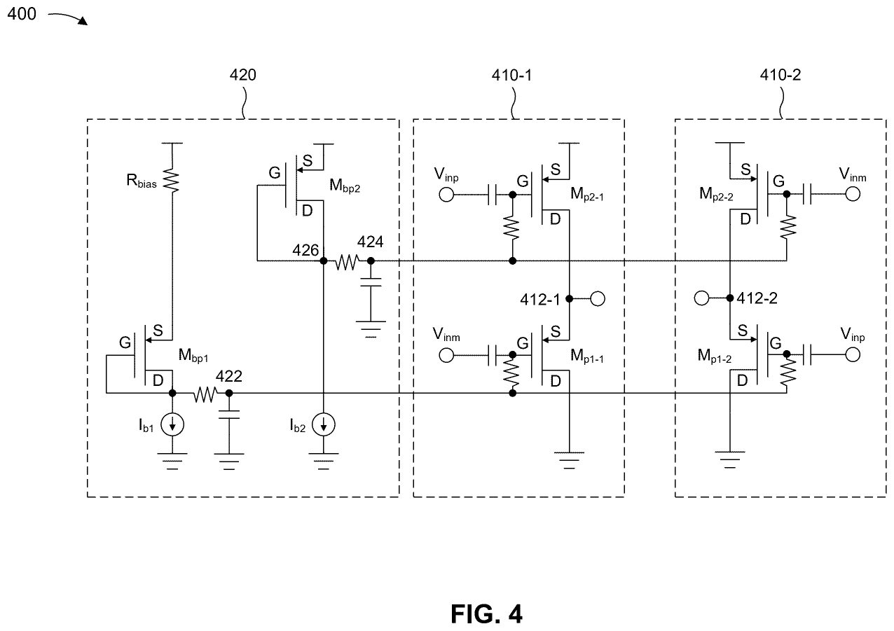

FIG. 4 is a diagram illustrating an example buffer 400 and associated bias circuit 420, in accordance with the present disclosure. As shown in FIG. 4, the buffer 400 includes a first branch 410-1 and a second branch 410-2, where the first branch 410-1 and the second branch 410-2 each include a pair of transistors arranged in a common source and source follower configuration, as described above. As further shown in FIG. 4, the buffer 400 is coupled to a bias circuit 420 that may generate a first bias voltage provided to a first transistor in each branch 410 and a second bias voltage provided to a second transistor in each branch 410. Furthermore, as described herein, the bias voltage provided to one of the transistors is a source follower bias that also sets an output common mode voltage. In the configuration illustrated in FIG. 4, the buffer branches 410 are implemented with PMOS transistors (e.g., with each branch including a first PMOS transistor and a second PMOS transistor arranged in a common source and source follower configuration, for example similar to the PP common source and source follower buffer 380-5 in FIG. 3), and the buffer 400 is referred to as a “PP buffer” below. It will be understood, however, that the branches 410 may instead be implemented with NMOS transistors (e.g., similar to the NN common source and source follower buffer 380-4 in FIG. 3), and that an equivalent buffer circuit may be implemented for use with such NN buffer.

As shown in FIG. 4, the first branch 410-1 of the PP buffer 400 includes a first PMOS transistor Mₚ₁₋₁ having a gate coupled to a negative input voltage, Vinm (e.g., corresponding to a first output from the UPC), a source coupled to an output node 412-1 of the first branch 410-1 (e.g., corresponding to a first input to a DA), and a drain coupled to ground. As further shown in FIG. 4, the first branch 410-1 of the PP buffer 400 includes a second PMOS transistor Mₚ₂₋₁ having a gate coupled to a positive input voltage, Vinp (e.g., corresponding to a second output from the UPC), a source coupled to a supply voltage, and a drain coupled to the output node 412-1. In addition, as further shown, the first branch 410-1 includes a first capacitor arranged between the gate of the first PMOS transistor Mₚ₁₋₁ and the negative input voltage, a first resistor having a first terminal coupled between the first capacitor and the gate of the first PMOS transistor Mₚ₁₋₁ and a second terminal coupled to a first output node 422 from the bias circuit 420, a second capacitor arranged between the gate of the second PMOS transistor Mₚ₂₋₁ and the positive input voltage, and a second resistor having a first terminal coupled between the second capacitor and the gate of the second PMOS transistor Mₚ₂₋₂ and a second terminal coupled to a second output node 424 from the bias circuit 420. Furthermore, as shown in FIG. 4, the second branch 410-2 is generally a mirror image of the first branch 410-1, except that the gate of the first PMOS transistor Mₚ₁₋₂ is coupled to the positive input voltage and the gate of the second PMOS transistor Mₚ₂₋₂ is coupled to the negative input voltage. As described herein, the first branch 410-1 and the second branch 410-2 each include a pair of PMOS transistors, which may drive an NMOS-based DA. In some aspects, each branch 410 includes one PMOS transistor driven by the negative input voltage and one PMOS transistor driven by the positive input voltage to provide a differential gain at the respective outputs 412 (e.g., that approaches 2), in addition to common mode noise filtering (e.g., because the common mode noise generated by the PMOS transistor pairs in each branch 410 cancel).

Furthermore, as shown in FIG. 4, the bias circuit 420 includes a first path associated with the first output node 422 to generate a first bias voltage for the first transistors Mₚ₁₋₁ and Mₚ₁₋₂ that operate as source follower amplifiers in each branch 410, where the first bias voltage controls an output common mode voltage. For example, as shown, the first path includes a first current source I_{b1} coupled to a (gate and drain of a) first diode-connected PMOS transistor M_{bp1} (e.g., where the first diode-connected PMOS transistor M_{bp1} includes a gate connected to a drain) and a bias resistor R_{bias} coupled between a source of the first diode-connected PMOS transistor M_{bp1} and a supply voltage. In addition, the first path includes a capacitor having a first terminal coupled to the first output node 422 and a second terminal coupled to ground, and a resistor having a first terminal coupled to the first output node 422 and a second terminal coupled to the first current source I_{b1} and to the gate and drain of first diode-connected PMOS transistor M_{bp1}. Similarly, the bias circuit 420 includes a second path associated with the second output node 424 to generate a second bias voltage for the second transistors Mₚ₂₋₁ and Mₚ₂₋₂ that operate as common source amplifiers in each branch 410. For example, as shown, the second path includes a second current source I_{b2} coupled to a (gate and drain of a) second diode-connected PMOS transistor M_{bp2} (e.g., where the second diode-connected PMOS transistor M_{bp2} includes a gate and a drain that are connected at a node 426), a resistor coupled between the second output node 424 and the node 426 connecting the gate and the drain of the second diode-connected PMOS transistor M_{bp2}, and a capacitor having a first terminal coupled to the second output node 424 and a second terminal coupled to ground.

Accordingly, as described herein, the output common mode voltage (set by the first bias voltage at the first output node 422) is determined by I_{b1}R_{bias}, a drain saturation voltage V_{dsat} of the first transistor Mₚ₁ in each branch is respectively determined by I_{b1} and a size of the first diode-connected PMOS transistor M_{bp1}, a drain saturation voltage V_{dsat} of the second transistor Mₚ₂ in each branch is respectively determined by I_{b2} and a size of the second diode-connected PMOS transistor M_{bp2}, and the size of the PMOS transistors Mₚ₁ and Mₚ₂ in each branch 410 set transconductances of the PMOS transistors Mₚ₁ and Mₚ₂. Furthermore, the drain saturation voltages V_{dsat} and the transconductances of the PMOS transistors Mₚ₁ and Mₚ₂ may be optimized for a gain, bandwidth, and/or linearity associated with the PP buffer 400 (or amplifier) for a given load. For example, a differential gain of the PP buffer 400 is about

$$\frac{{g}_{mp 2}}{{g}_{mp 1}} + \frac{{g}_{mp 1}}{1 + {Z}_{l} {g}_{mp 1}} ,$$

and common mode cancellation is achieved by the PP buffer 400 having a common mode gain of about

$$\frac{{g}_{mp 2}}{{g}_{mp 1}} - \frac{{g}_{mp 1}}{1 + {Z}_{l} {g}_{mp 1}} ,$$

where gₘₚ₁ and gₘₚ₂ are the respective transconductances of the PMOS transistors Mₚ₁ and Mₚ₂ in each branch 410 and Zₗ is a load impedance of the PP buffer 400 (not shown in FIG. 4).

As indicated above, FIG. 4 is provided as an example. Other examples may differ from what is described with regard to FIG. 4.

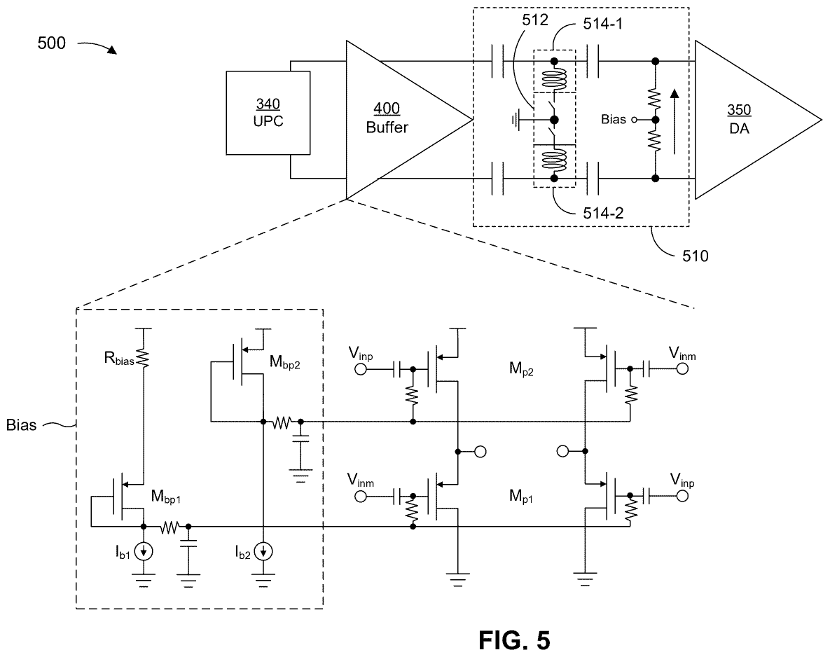

FIG. 5 is a diagram illustrating an example architecture 500 using a buffer 400 that includes a PP (common source and source follower) buffer and associated bias circuit to provide a UPC-DA interface and a high-pass filter 510 for noise filtering at an output from the buffer 400, in accordance with the present disclosure. For example, as shown in FIG. 5, the architecture 500 includes a UPC 340, a DA 350, and a buffer 400 that provides an interface from an output of the UPC 340 to an input of the DA 350. Furthermore, as shown, the buffer 400 has a design that corresponds to the PP buffer 400 and associated bias circuit shown in FIG. 4. As further shown in FIG. 5, the high pass filter 510 includes a block 512 with a set of output switches and ground routing.

As shown in FIG. 5, the high pass filter 510 is a high pass resonant circuit (also known as an LC circuit when made from an inductor (L) connected to a capacitor (C)) comprising a pair of inductors 514-1, 514-2 that each include a first terminal connected to a switch in block 512 and a second terminal connected between a pair of capacitors (e.g., the architecture 500 may include multiple segments that implement the buffer 400, and the switch may be present to connect the high pass filter 510 to an active segment and to disconnect the high pass filter 510 from deactivated segments). In some aspects, the high pass filter 510 may be used at the output from the buffer 400 to filter out flicker noise that would otherwise be up-converted by the DA 350 and significantly degrade overall noise performance. For example, although the buffer 400 in a standalone configuration has relatively low noise, the buffer 400 may generate low frequency and flicker noise that is upconverted when placed in a signal path with the DA 350 (e.g., because the DA 350 may act as a mixer to upconvert low frequencies to an operating frequency when placed in a signal path with the buffer 400 due to linearity and efficiency requirements of the DA 350). Accordingly, in some aspects, the high pass LC circuit may act as a high pass filter, which does not require any tuning, and the inductors 340-1, 340-2 do not need to provide high performance and/or a high quality factor (Q) (e.g., a ratio of an inductive reactance to a resistance at a given frequency, representing inductor efficiency at that frequency) because the inductors 340-1, 340-2 are used only to filter low frequency noise. The inductors 340-1, 340-2 therefore may have a small size (e.g., about 6 nano Henrys (nH)) and a low Q (e.g., 4 at 1.8 GHz). In addition, as shown, a bias and a pair of resistors may be provided at an interface between the high pass filter 510 and the DA 350 (e.g., to set an operating point of the the high pass filter 510 and/or the DA 350).

As indicated above, FIG. 5 is provided as an example. Other examples may differ from what is described with regard to FIG. 5.

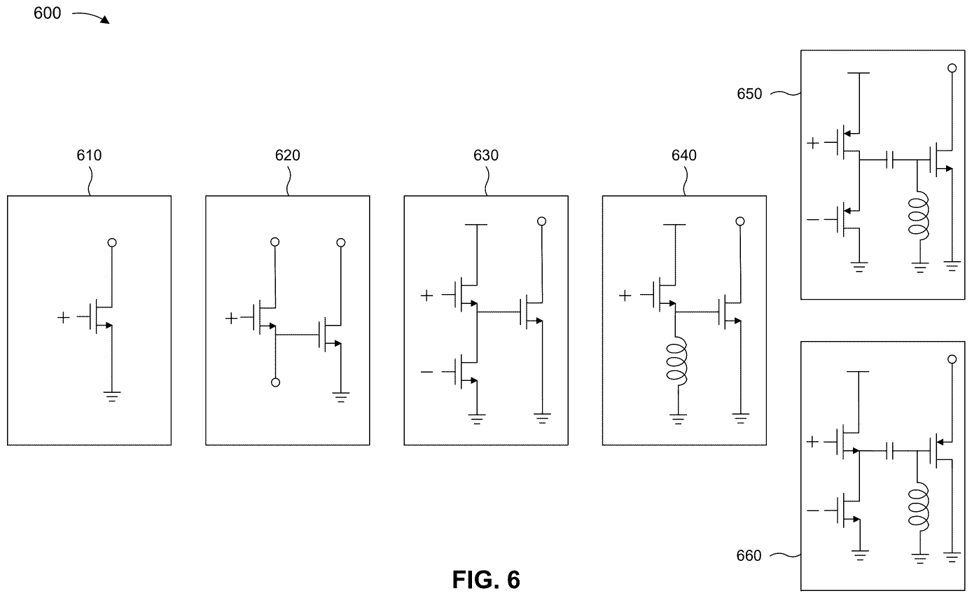

FIG. 6 is a diagram illustrating examples 600 of amplifier circuits, in accordance with the present disclosure. In particular, examples 600 depict various amplifier designs, including a transconductance (Gm) circuit 610 that includes a single transistor, and a Darlington Gm circuit 620 that includes a pair of bipolar transistors with a source of a first transistor connected to a gate of a second transistor such that a current amplified by the first transistor is further amplified by the second transistor. As further shown in FIG. 6, the Darlington Gm circuit 620 may be modified to have an architecture 630 with a third NMOS transistor coupled to a negative input voltage (e.g., to improve linearity), or an architecture 640 where the third transistor is replaced by an inductor, which may be suitable for millimeter wave and IF power amplifiers. For example, the architecture 640 may provide a source follower amplifier to drive a power amplifier, with the inductor provided to enhance the frequency of operation. Further, FIG. 6 illustrates an amplifier circuit 650 that may represent a generalized form of a combined PP buffer and DA, as described herein. For example, the amplifier circuit 650 includes a PP buffer implemented with two PMOS transistors, with one PMOS transistor having a gate coupled to a positive input voltage and the other PMOS transistor having a gate coupled to a negative input voltage, which may complement an NMOS transistor used as a gain transistor in a DA (e.g., by providing a low input capacitance and wideband common mode rejection). Alternatively, an amplifier circuit 660 may include two NMOS transistors, with one NMOS transistor having a gate coupled to a positive input voltage and the other NMOS transistor having a gate coupled to a negative input voltage, to complement a PMOS transistor used in a DA. Furthermore, the amplifier circuits 650, 660 may include an inductor and a capacitor coupled between the transistors used in the buffer of the amplifier circuit 650, 660 and the complementary transistor used in the DA, providing an LC circuit or high-pass filter to filter the flicker noise and low frequency noise generated by the transistors in the amplifier circuit 650, 660 (e.g., to prevent the flicker noise and low frequency noise from being upconverted, which may be particularly useful for RF applications such as sub-6 GHz bands that have stringent specifications on noise and baseband harmonics, among other examples).

As indicated above, FIG. 6 is provided as an example. Other examples may differ from what is described with regard to FIG. 6.

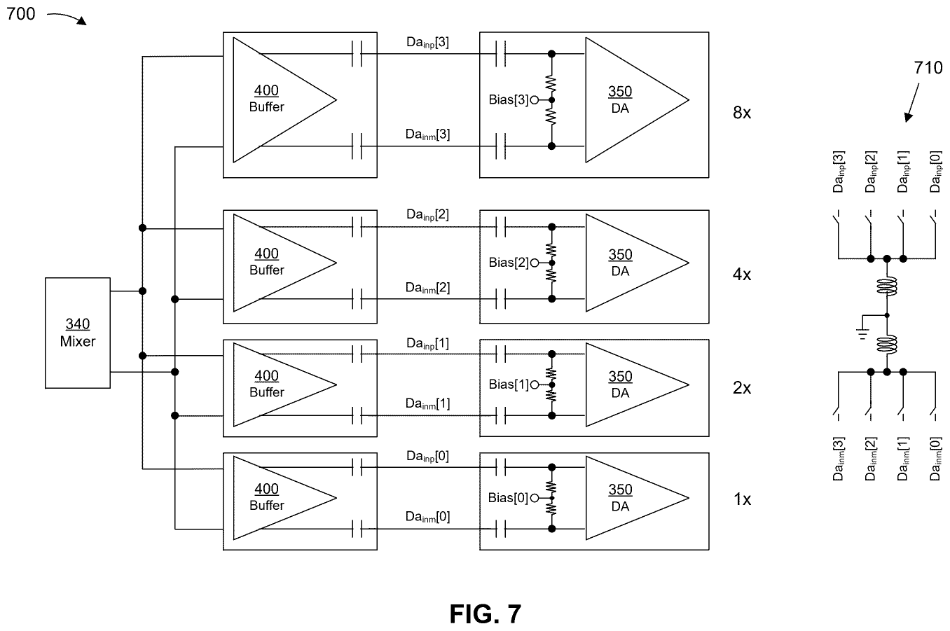

FIG. 7 is a diagram illustrating an example architecture 700 that includes one or more DA and buffer segments to reduce talk-time power consumption in a wireless transceiver, in accordance with the present disclosure. For example, in order to provide amplification or gain at the interface between a mixer (or UPC) 340 and a DA 350, the buffer 400 described herein may draw a current that results in increased power consumption. In typical wireless transmitter applications, the power consumption is dominated by the power amplifiers. However, at talk time (e.g., during transmission), an overall design goal is to reduce power consumption as much as possible for each component in the transmit signal path. Accordingly, architecture 700 may be designed to reduce the current consumption, and therefore the power consumption, of the buffer 400.

For example, as shown in FIG. 7, the architecture 700 may divide the buffer 400 and the DA 350 into multiple segments. The size of the buffer 400 and the DA 350 may vary among the multiple segments, as illustrated, or the segments may have equal size. For example, in FIG. 7, the buffer 400 and the DA 350 are divided into multiple segments, where a first (bottom-most) segment has a 1× size, a second segment has a size that is double the size of the first segment, a third segment has a size that is double the size of the second segment (four times the size of the first segment), and a fourth segment has a size that is double the size of the third segment (four times the size of the second segment and eight times the size of the first segment). Accordingly, each segment (e.g., in both the buffer 400 and the DA 350) may have a different power consumption, where a segment that has a smallest buffer 400 and DA 350 that can satisfy a required output power may be used for talk time output power, Pout. Furthermore, unused segments may be essentially deactivated. For example, a bias for any unused segments may be pulled to ground to reduce the capacitance loading and allow the smallest suitable segment (or smallest suitable combination of segments) to be used at talk time, thus reducing power consumption as much as possible.

In some aspects, as shown by reference number 710, the architecture 700 may include a high-pass filter that is shared among the multiple segments and switchably coupled only to the active segment. For example, as described herein, the architecture 700 may generally include n segments, where n is an integer greater than one and the DA in the n^{th} segment has a first input coupled to a positive input voltage (denoted Daᵢₙₚ[n] and a second input coupled to a negative input voltage (denoted Daᵢₙₙ[n]). In some aspects, as shown by reference number 710, the inputs of the DA in each segment may be coupled to a respective switch, which may be in the open position when the corresponding segment is deactivated or in the closed position when the corresponding segment is active. For example, as shown by reference number 710, the inputs of the DA in each segment may be switchably connected to one or more inductors that form a high-pass filter (e.g., as described above with respect to FIG. 5), where the switch may be closed for the segment used to provide the talk time output power such that the high-pass filter may filter flicker noise for the active segment. Furthermore, the switches may be open for all other (unused/deactivated) segments to disconnect the high-pass filter from the unused/deactivated) segments.

As indicated above, FIG. 7 is provided as an example. Other examples may differ from what is described with regard to FIG. 7.

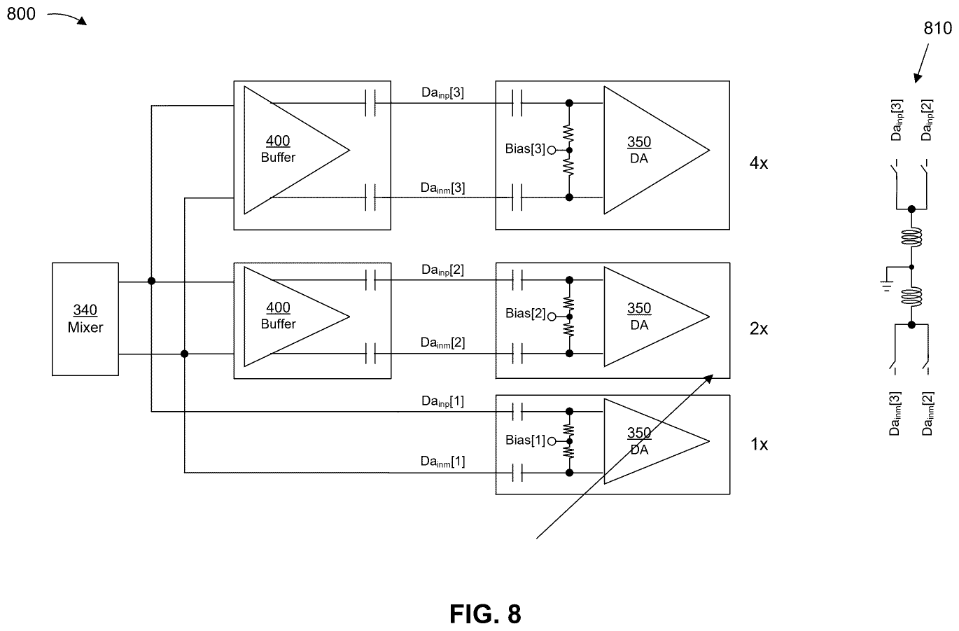

FIG. 8 is a diagram illustrating an example architecture 800 that includes one or more DA and buffer segments to reduce talk-time power consumption in a wireless transceiver, in accordance with the present disclosure. More particularly, the architecture 800 is generally similar to the architecture 700, in that the buffer 400 and the DA 350 are divided into multiple segments, where the size of the buffer 400 and the DA 350 may vary among the multiple segments. However, in the architecture 800, one or more of the segments only include a DA 350, with no buffer 400. For example, in FIG. 8, the architecture 800 includes three segments, where a least significant bit (LSB) (e.g., bottom-most) segment has a DA-only architecture, and one or more most significant bit (MSB) segments include a buffer 400 and DA 350 with varying sizes. In some aspects, the DA in the segment with the DA-only architecture may be a variable DA (e.g., with a tunable or adjustable gain). Accordingly, the architecture 800 may generally be divided into N segments, where one segment has a DA-only architecture and N−1 segments have an architecture with a buffer 400 and a DA 350. In this case, at talk time, segments with a buffer 400 and a DA 350 may be selectively switched off to reduce power consumption.

In some aspects, as shown by reference number 810, the architecture 700 may include a high-pass filter that is shared among the segments that include a buffer 400, and the high-pass filter is switchably coupled only to the active segment. For example, as shown by reference number 810, the inputs of the DA in each segment with a buffer 400 may be coupled to a respective switch, which may be in the open position when the corresponding segment is deactivated or in the closed position when the corresponding segment is active. Accordingly, the inputs of the DA in each segment with a buffer 400 may be switchably connected to one or more inductors that form a high-pass filter (e.g., as described above with respect to FIG. 5), where the switch may be closed for the segment used to provide the talk time output power such that the high-pass filter may filter flicker noise for the active segment. Furthermore, the switches may be open for all other (unused/deactivated) segments to disconnect the high-pass filter from the unused/deactivated) segments. In the architecture 800 shown in FIG. 8, where there is one DA-only segment, a size of the inductor(s) that form the high-pass filter may be determined by the smallest segment that includes a buffer 400 (e.g., the MSB−1^{th} segment).

As indicated above, FIG. 8 is provided as an example. Other examples may differ from what is described with regard to FIG. 8.

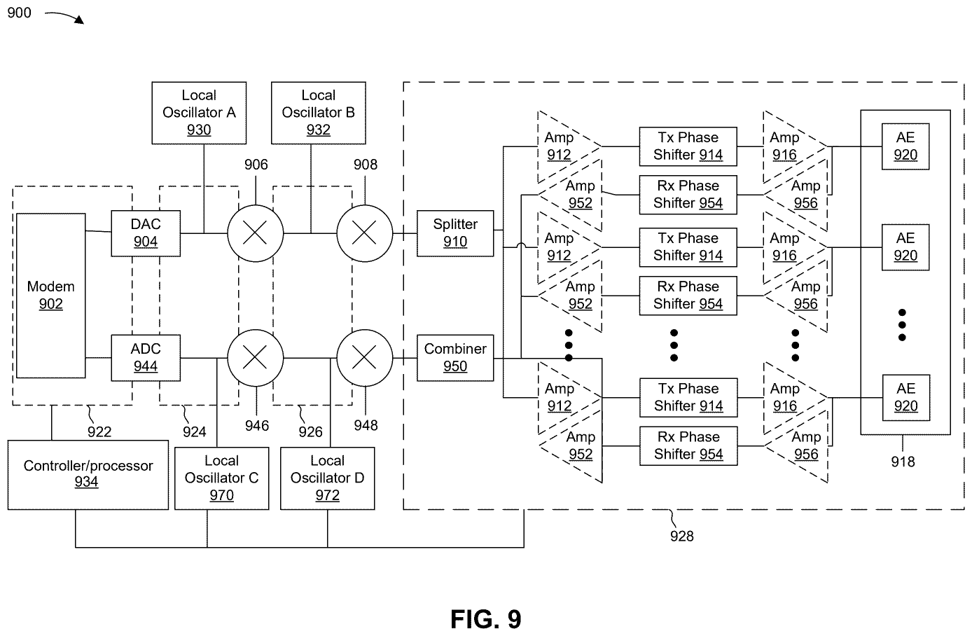

FIG. 9 is a diagram illustrating an example beamforming architecture 900, in accordance with the present disclosure. The beamforming architecture 900 may be implemented in the electronic device 102 shown in FIG. 1, the transceiver 200 shown in FIG. 2, the transmit signal path 300 shown in FIG. 3, or the like. Additionally, or alternatively, the beamforming architecture 900 may include or may implement the buffer 400 shown in FIG. 4, the architecture 500 shown in FIG. 5, the amplifier circuit 650 shown in FIG. 6, the architecture 700 shown in FIG. 7, and/or the architecture 800 shown in FIG. 8 (e.g., to provide an interface between one or more mixers and one or more amplifiers, such as mixer 906 and an amplifier (not shown) that precedes mixer 908 to amplify a signal before the signal is transmitted over a cable).

As described herein, FIG. 9 illustrates example hardware components of a wireless communication device in accordance with certain aspects of the disclosure. The illustrated components may include those that may be used for antenna element selection and/or for beamforming for transmission of wireless signals. There are numerous architectures for antenna element selection and implementing phase shifting, only one example of which is illustrated in FIG. 9. The beamforming architecture 900 may include a modem (modulator/demodulator) 902, a DAC 904, a first mixer 906, a second mixer 908, and a splitter 910. The beamforming architecture 900 may also include multiple first amplifiers 912, multiple phase shifters 914, multiple second amplifiers 916, and an antenna array 918 that includes multiple antenna elements 920.

Transmission lines or other waveguides, wires, and/or traces are shown to connect components to illustrate how signals transmitted travel between components. Reference numbers 922, 924, 926, and 928 indicate regions in the beamforming architecture 900 in which different types of signals travel or are processed. Specifically, reference number 922 indicates a region in which digital baseband signals travel or are processed, reference number 924 indicates a region in which analog baseband signals travel or are processed, reference number 926 indicates a region in which analog IF signals travel or are processed, and reference number 928 indicates a region in which analog RF signals travel or are processed. The beamforming architecture 900 also includes an LO A 930, an LO B 932, and a controller/processor 934.

Each of the antenna elements 920 may include one or more sub-elements for radiating or receiving RF signals. For example, a single antenna element 920 may be configured to operate in in multiple polarizations and/or include a first sub-element cross-polarized with a second sub-element that can be used to independently transmit cross-polarized signals. The antenna elements 920 may include patch antennas, dipole antennas, or other types of antennas arranged in a linear pattern, a two dimensional pattern, or another pattern. A spacing between antenna elements 920 may be such that signals with a desired wavelength transmitted separately by the antenna elements 920 may interact or interfere (e.g., to form a desired beam). For example, given an expected range of wavelengths or frequencies, the spacing may provide a quarter wavelength, half wavelength, or other fraction of a wavelength of spacing between neighboring antenna elements 920 to allow for interaction or interference of signals transmitted by the separate antenna elements 920 within that expected range.

The modem 902 may process and generate digital baseband signals and may also control operation of the DAC 904, the first and second mixers 906 and 908, the splitter 910, the first amplifiers 912, the phase shifters 914, and/or the second amplifiers 916 to transmit signals via one or more or all of the antenna elements 920. The modem 902 may process signals and control operation in accordance with a communication standard such as a wireless communication standard. The DAC 904 may convert digital baseband signals received from the modem 902 (and that are to be transmitted) into analog baseband signals. The first mixer 906 may up-convert analog baseband signals to analog IF signals within an IF using an LO A 930. For example, the first mixer 906 may mix the signals with an oscillating signal generated by the LO A 930 to shift the baseband analog signals to the IF. In some aspects, some processing or filtering (not shown) may take place at the IF. The second mixer 908 may up-convert the analog IF signals to analog RF signals using the LO B 932. Similar to the first mixer, the second mixer 908 may mix the signals with an oscillating signal generated by the LO B 932 to shift the IF analog signals to the RF or the frequency at which signals will be transmitted or received. The modem 902 and/or the controller/processor 934 may adjust the frequency of the LO A 930 and/or the LO B 932 so that a desired IF and/or RF frequency is produced and used to facilitate processing and transmission of a signal within a desired bandwidth.

In the illustrated beamforming architecture 900, signals up-converted by the second mixer 908 are split or duplicated into multiple signals by the splitter 910. The splitter 910 in the beamforming architecture 900 may split the RF signal into multiple identical or nearly identical RF signals. In other examples, the split may take place with any type of signal, including with baseband digital, baseband analog, or IF analog signals. Each signal may correspond to an antenna element 920, and the signal travels through and is processed by the amplifiers 912, 916, the phase shifters 914, and/or other elements corresponding to the respective antenna element 920 to be provided to and transmitted by the corresponding antenna element 920 of the antenna array 918. For example, the splitter 910 may be an active splitter connected to a power supply to provide some gain so that RF signals exiting the splitter 910 are at a power level equal to or greater than the signal entering the splitter 910. In another example, the splitter 910 is a passive splitter that is not connected to power supply and the RF signals exiting the splitter 910 may be at a lower power than the RF signal entering the splitter 910.

After being split by the splitter 910, the resulting RF signals may enter an amplifier, such as a first amplifier 912, or a phase shifter 914 corresponding to an antenna element 920. In other examples, LO path phase shifting is implemented instead of the illustrated signal path phase shifting. The first and second amplifiers 912, 916 are illustrated with dashed lines because one or both might not be necessary in some aspects. In some aspects, both the first amplifier 912 and second amplifier 916 are present. In some aspects, neither the first amplifier 912 nor the second amplifier 916 is present. In some aspects, one of the two amplifiers 912, 916 is present but not the other. By way of example, if the splitter 910 is an active splitter, the first amplifier 912 may not be used. By way of further example, if the phase shifter 914 is an active phase shifter that can provide a gain, the second amplifier 916 might not be used.

The amplifiers 912, 916 may provide a desired level of positive or negative gain. A positive gain (positive dB) may be used to increase an amplitude of a signal for radiation by a specific antenna element 920. A negative gain (negative dB) may be used to decrease an amplitude and/or suppress radiation of the signal by a specific antenna element. Each of the amplifiers 912, 916 may be controlled independently (e.g., by the modem 902 or the controller/processor 934) to provide independent control of the gain for each antenna element 920. For example, the modem 902 and/or the controller/processor 934 may have at least one control line connected to each of the splitter 910, first amplifiers 912, phase shifters 914, and/or second amplifiers 916 that may be used to configure a gain to provide a desired amount of gain for each component and thus each antenna element 920.

The phase shifter 914 may provide a configurable phase shift or phase offset to a corresponding RF signal to be transmitted. The phase shifter 914 may be a passive phase shifter not directly connected to a power supply. Passive phase shifters might introduce some insertion loss. The second amplifier 916 may boost the signal to compensate for the insertion loss. The phase shifter 914 may be an active phase shifter connected to a power supply such that the active phase shifter provides some amount of gain or prevents insertion loss. The settings of each phase shifter 914 are independent, meaning that each can be independently set to provide a desired amount of phase shift or the same amount of phase shift or some other configuration. The modem 902 and/or the controller/processor 934 may have at least one control line connected to each of the phase shifters 914 and which may be used to configure the phase shifters 914 to provide a desired amount of phase shift or phase offset between antenna elements 920.

In the illustrated beamforming architecture 900, RF signals received by the antenna elements 920 are provided to one or more first amplifiers 956 to boost the signal strength. The first amplifiers 956 may be connected to the same antenna arrays 918 (e.g., for time division duplex (TDD) operations). The first amplifiers 956 may be connected to different antenna arrays 918. The boosted RF signal is input into one or more phase shifters 954 to provide a configurable phase shift or phase offset for the corresponding received RF signal to enable reception via one or more Rx beams. The phase shifter 954 may be an active phase shifter or a passive phase shifter. The settings of the phase shifters 954 are independent, meaning that each can be independently set to provide a desired amount of phase shift or the same amount of phase shift or some other configuration. The modem 902 and/or the controller/processor 934 may have at least one control line connected to each of the phase shifters 954 and which may be used to configure the phase shifters 954 to provide a desired amount of phase shift or phase offset between antenna elements 920 to enable reception via one or more Rx beams.

The outputs of the phase shifters 954 may be input to one or more second amplifiers 952 for signal amplification of the phase shifted received RF signals. The second amplifiers 952 may be individually configured to provide a configured gain. The second amplifiers 952 may be individually configured to provide an amount of gain to ensure that the signals input to combiner 950 have the same magnitude. The amplifiers 952 and/or 956 are illustrated in dashed lines because they might not be necessary in some aspects. In some aspects, both the amplifier 952 and the amplifier 956 are present. In another aspect, neither the amplifier 952 nor the amplifier 956 are present. In other aspects, one of the amplifiers 952, 956 is present but not the other.

In the beamforming architecture 900, signals output by the phase shifters 954 (via the amplifiers 952 when present) are combined in combiner 950. The combiner 950 may combine the RF signal into a signal. The combiner 950 may be a passive combiner (e.g., not connected to a power source), which may result in some insertion loss. The combiner 950 may be an active combiner (e.g., connected to a power source), which may result in some signal gain. When combiner 950 is an active combiner, it may provide a different (e.g., configurable) amount of gain for each input signal so that the input signals have the same magnitude when they are combined. When combiner 950 is an active combiner, the combiner 950 may not need the second amplifier 952 because the active combiner may provide the signal amplification.

The output of the combiner 950 is input into mixers 948 and 946. Mixers 948 and 946 generally down-convert the received RF signal using inputs from LOs 972 and 970, respectively, to create intermediate or baseband signals that carry the encoded and modulated information. The output of the mixers 948 and 946 are input into an ADC 944 for conversion to digital signals. The digital signals output from ADC 944 are input to modem 902 for baseband processing, such as decoding, de-interleaving, or similar operations.

The beamforming architecture 900 is given by way of example only to illustrate an architecture for transmitting and/or receiving signals. In some cases, the beamforming architecture 900 and/or each portion of the beamforming architecture 900 may be repeated multiple times within an architecture to accommodate or provide an arbitrary number of RF chains, antenna elements, and/or antenna panels. Furthermore, numerous alternate architectures are possible and contemplated. For example, although only a single antenna array 918 is shown, two, three, or more antenna arrays may be included, each with one or more of their own corresponding amplifiers, phase shifters, splitters, mixers, DACs, ADCs, and/or modems. For example, a single UE may include two, four, or more antenna arrays for transmitting or receiving signals at different physical locations on the UE or in different directions.

Furthermore, mixers, splitters, amplifiers, phase shifters and other components may be located in different signal type areas (e.g., represented by different ones of the reference numbers 922, 924, 926, 928) in different implemented architectures. For example, a split of the signal to be transmitted into multiple signals may take place at the analog RF, analog IF, analog baseband, or digital baseband frequencies in different examples. Similarly, amplification and/or phase shifts may also take place at different frequencies. For example, in some aspects, one or more of the splitter 910, amplifiers 912, 916, or phase shifters 914 may be located between the DAC 904 and the first mixer 906 or between the first mixer 906 and the second mixer 908. In one example, the functions of one or more of the components may be combined into one component. For example, the phase shifters 914 may perform amplification to include or replace the first and/or or second amplifiers 912, 916. By way of another example, a phase shift may be implemented by the second mixer 908 to obviate the need for a separate phase shifter 914. This technique is sometimes called LO phase shifting. In some aspects of this configuration, there may be multiple IF to RF mixers (e.g., for each antenna element chain) within the second mixer 908, and the LO B 932 may supply different local oscillator signals (with different phase offsets) to each IF to RF mixer.

The modem 902 and/or the controller/processor 934 may control one or more of the other components 904 through 972 to select one or more antenna elements 920 and/or to form beams for transmission of one or more signals. For example, the antenna elements 920 may be individually selected or deselected for transmission of a signal (or signals) by controlling an amplitude of one or more corresponding amplifiers, such as the first amplifiers 912 and/or the second amplifiers 916. Beamforming includes generation of a beam using multiple signals on different antenna elements, where one or more or all of the multiple signals are shifted in phase relative to each other. The formed beam may carry physical or higher layer reference signals or information. As each signal of the multiple signals is radiated from a respective antenna element 920, the radiated signals interact, interfere (constructive and destructive interference), and amplify each other to form a resulting beam. The shape (such as the amplitude, width, and/or presence of side lobes) and the direction (such as an angle of the beam relative to a surface of the antenna array 918) can be dynamically controlled by modifying the phase shifts or phase offsets imparted by the phase shifters 914 and amplitudes imparted by the amplifiers 912, 916 of the multiple signals relative to each other. The controller/processor 934 may be located partially or fully within one or more other components of the beamforming architecture 900. For example, the controller/processor 934 may be located within the modem 902 in some aspects.

As indicated above, FIG. 9 is provided as an example. Other examples may differ from what is described with regard to FIG. 9.

The following provides an overview of some Aspects of the present disclosure:

Aspect 1: A circuit, comprising: an up-converter mixer configured with differential outputs; a driver amplifier including a gain transistor; and a buffer to interface the up-converter mixer to the driver amplifier, wherein the buffer comprises a stacked pair of transistors coupled between a supply voltage and a ground, wherein a source of a first transistor of the stacked pair of transistors is connected to a drain of a second transistor of the stacked pair of transistors, wherein the drain and the source are coupled to the gain transistor, wherein a gate of each of the stacked pair of transistors is coupled to a respective output of the differential outputs, and wherein the stacked pair of transistors are complementary to the gain transistor.

Aspect 2: The circuit of Aspect 1, wherein the buffer includes one or more branches that each include a stacked pair of transistors, and wherein the stacked pair of transistors in each branch comprises: a first PMOS transistor having a source coupled to an output node, a gate coupled to an input voltage and to a first bias voltage, and a drain coupled to ground; and a second PMOS transistor having a source coupled to a supply voltage, a gate coupled to an input voltage and to a second bias voltage, and a drain coupled to the output node.

Aspect 3: The circuit of Aspect 2, further comprising: a bias circuit configured to generate the first bias voltage and the second bias voltage.

Aspect 4: The circuit of Aspect 3, wherein the bias circuit comprises: a current source; a diode-connected PMOS transistor having a source coupled to the supply voltage, a gate coupled to the current source and an output node, and a drain coupled to the current source and the output node; and a bias resistor coupled between the supply voltage and the source of the diode-connected PMOS transistor, wherein the first bias voltage sets an output common mode voltage based on a current generated by the current source and a resistance of the bias resistor.

Aspect 5: The circuit of Aspect 3, wherein the bias circuit comprises: a current source; a diode-connected PMOS transistor having a source coupled to the supply voltage, a gate coupled to the current source and an output node, and a drain coupled to the current source and the output node; and a resistor coupled between the output node and a node coupled to the current source, the gate of the diode-connected PMOS transistor, and the drain of the diode-connected PMOS transistor, wherein the second bias voltage is based on a current generated by the current source and a resistance of the resistor.

Aspect 6: The circuit of any of Aspects 1-5, further comprising: a high pass filter configured to filter flicker noise and low frequency noise at an interface between the buffer and the driver amplifier.

Aspect 7: The circuit of Aspect 6, wherein the high pass filter comprises: a first pair of capacitors coupled to a first output node of the buffer; a second pair of capacitors coupled to a second output node of the buffer; a first inductor and a second inductor that each have a first terminal and a terminal, wherein: the first terminal of the first inductor is coupled between the first pair of capacitors and the second terminal of the first inductor is switchably coupled to ground or to the second terminal of the second conductor, and the first terminal of the second inductor is coupled between the second pair of capacitors and the second terminal of the second inductor is switchably coupled to ground or to the second terminal of the first conductor.

Aspect 8: The circuit of any of Aspects 1-7, wherein the buffer has a common source and source follower configuration.

Aspect 9: A buffer, comprising: a plurality of branches, wherein the plurality of branches each include: a first PMOS transistor having a source coupled to an output node, a gate coupled to an input voltage and to a first bias voltage, and a drain coupled to ground; and a second PMOS transistor having a source coupled to a supply voltage, a gate coupled to an input voltage and to a second bias voltage, and a drain coupled to the output node.

Aspect 10: The buffer of Aspect 9, further comprising: a current source; a diode-connected PMOS transistor having a source coupled to the supply voltage, a gate coupled to the current source and an output node, and a drain coupled to the current source and the output node; and a bias resistor coupled between the supply voltage and the source of the diode-connected PMOS transistor, wherein the first bias voltage sets a common mode output voltage based on a current generated by the current source and a resistance of the bias resistor.

Aspect 11: The buffer of Aspect 10, wherein a drain saturation voltage of the first PMOS transistor in each branch is based on the current generated by the current source and a size of the diode-connected PMOS transistor.

Aspect 12: The buffer of any of Aspects 9-11, further comprising: a current source; a diode-connected PMOS transistor having a source coupled to the supply voltage, a gate coupled to the current source and an output node, and a drain coupled to the current source and the output node; and a resistor coupled between the output node and a node coupled to the current source, the gate of the diode-connected PMOS transistor, and the drain of the diode-connected PMOS transistor, wherein the second bias voltage is based on a current generated by the current source and a resistance of the resistor.

Aspect 13: The buffer of Aspect 10, wherein a drain saturation voltage of the second PMOS transistor in each branch is based on the current generated by the current source and a size of the diode-connected PMOS transistor.

Aspect 14: The buffer of any of Aspects 9-13, wherein a differential gain and a common mode gain between the respective output nodes is based on a transconductance of the first PMOS transistor in each branch, a transconductance of the second PMOS transistor in each branch, and an impedance of a load coupled to the output node.

Aspect 15: A transmission circuit, comprising: a mixer; a plurality of segments each configured to be selectively deactivated, wherein each segment of the plurality of segments includes: a DA; and a buffer to interface the mixer to the DA in the segment, wherein each buffer comprises a pair of PMOS transistors arranged in a common source and source follower configuration.

Aspect 16: The transmission circuit of Aspect 15, wherein the pair of PMOS transistors in each segment comprise: a first PMOS transistor having a source coupled to an output node, a gate coupled to an input voltage and to a first bias voltage, and a drain coupled to ground; and a second PMOS transistor having a source coupled to a supply voltage, a gate coupled to an input voltage and to a second bias voltage, and a drain coupled to the output node.

Aspect 17: The transmission circuit of any of Aspects 15-16, wherein the DA and the buffer have a different size in each of the plurality of segments.

Aspect 18: The transmission circuit of Aspect 16, wherein only a segment, of the plurality of segments, with a smallest size that satisfies a power requirement is used at a talk time associated with the transmission circuit, and wherein a bias associated with each unused segment is pulled to ground at the talk time.

Aspect 19: The transmission circuit of any of Aspects 15-18, further comprising: a single segment that includes a DA and no buffer.

Aspect 20: The transmission circuit of Aspect 18, wherein only the single segment with the DA and no buffer is used at a talk time associated with the circuit, and wherein a bias associated with the plurality of segments that include a DA and a buffer is pulled to ground at the talk time.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 1-20.

Aspect 24: A computer program product comprising instructions or code for executing one or more operations recited in one or more of Aspects 1-20.

The foregoing disclosure provides illustration and description but is not intended to be exhaustive or to limit the aspects to the precise forms disclosed. Modifications and variations may be made in light of the above disclosure or may be acquired from practice of the aspects.

The foregoing outlines features of various aspects so that those skilled in the art may better understand the aspects of the present disclosure. Those skilled in the art should appreciate that the present disclosure may be readily used as a basis for designing or modifying other processes and/or structures for carrying out the same purposes and/or achieving the same advantages of the aspects described herein. Those skilled in the art should also realize that such equivalent constructions do not depart from the spirit and scope of the present disclosure, and that various changes, substitutions, and alterations may be made herein without departing from the spirit and scope of the present disclosure.

As used herein, the term “component” is intended to be broadly construed as hardware or a combination of hardware and at least one of software or firmware. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (for example, a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based on or otherwise in association with” unless explicitly stated otherwise. Also, as used herein, the term “or” is intended to be inclusive when used in a series and may be used interchangeably with “and/or,” unless explicitly stated otherwise (for example, if used in combination with “either” or “only one of”). It should be understood that “one or more” is equivalent to “at least one.”

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set.

What is claimed is:

1. A circuit, comprising:
an up-converter mixer configured with differential outputs;
a driver amplifier including a gain transistor; and
a buffer to interface the up-converter mixer to the driver amplifier, wherein the buffer comprises a stacked pair of transistors coupled between a supply voltage and a ground, wherein a source of a first transistor of the stacked pair of transistors is connected to a drain of a second transistor of the stacked pair of transistors, wherein the drain and the source are coupled to the gain transistor, wherein a gate of each of the stacked pair of transistors is coupled to a respective output of the differential outputs, and wherein the stacked pair of transistors are complementary to the gain transistor.

2. The circuit of claim 1, wherein the buffer includes one or more branches that each include a stacked pair of transistors, and wherein the stacked pair of transistors in each branch comprises:
a first p-channel metal-oxide-semiconductor (PMOS) transistor having a source coupled to an output node, a gate coupled to an input voltage and to a first bias voltage, and a drain coupled to ground; and
a second PMOS transistor having a source coupled to a supply voltage, a gate coupled to an input voltage and to a second bias voltage, and a drain coupled to the output node.

3. The circuit of claim 2, further comprising:
a bias circuit configured to generate the first bias voltage and the second bias voltage.

4. The circuit of claim 3, wherein the bias circuit comprises:
a current source;
a diode-connected PMOS transistor having a source coupled to the supply voltage, a gate coupled to the current source and an output node, and a drain coupled to the current source and the output node; and
a bias resistor coupled between the supply voltage and the source of the diode-connected PMOS transistor, wherein the first bias voltage sets an output common mode voltage based on a current generated by the current source and a resistance of the bias resistor.

5. The circuit of claim 3, wherein the bias circuit comprises:
a current source;
a diode-connected PMOS transistor having a source coupled to the supply voltage, a gate coupled to the current source and an output node, and a drain coupled to the current source and the output node; and
a resistor coupled between the output node and a node coupled to the current source, the gate of the diode-connected PMOS transistor, and the drain of the diode-connected PMOS transistor, wherein the second bias voltage is based on a current generated by the current source and a resistance of the resistor.

6. The circuit of claim 1, further comprising:
a high pass filter configured to filter flicker noise and low frequency noise at an interface between the buffer and the driver amplifier.

7. The circuit of claim 6, wherein the high pass filter comprises:
a first pair of capacitors coupled to a first output node of the buffer;
a second pair of capacitors coupled to a second output node of the buffer;
a first inductor and a second inductor that each have a first terminal and a terminal, wherein:
the first terminal of the first inductor is coupled between the first pair of capacitors and the second terminal of the first inductor is switchably coupled to ground or to the second terminal of the second conductor, and
the first terminal of the second inductor is coupled between the second pair of capacitors and the second terminal of the second inductor is switchably coupled to ground or to the second terminal of the first conductor.

8. The circuit of claim 1, wherein the buffer has a common source and source follower configuration.

9. A buffer, comprising:
a plurality of branches, wherein the plurality of branches each include:
a first p-channel metal-oxide-semiconductor (PMOS) transistor having a source coupled to an output node, a gate coupled to an input voltage and to a first bias voltage, and a drain coupled to ground; and
a second PMOS transistor having a source coupled to a supply voltage, a gate coupled to an input voltage and to a second bias voltage, and a drain coupled to the output node.

10. The buffer of claim 9, further comprising:
a current source;
a diode-connected PMOS transistor having a source coupled to the supply voltage, a gate coupled to the current source and an output node, and a drain coupled to the current source and the output node; and
a bias resistor coupled between the supply voltage and the source of the diode-connected PMOS transistor, wherein the first bias voltage sets a common mode output voltage based on a current generated by the current source and a resistance of the bias resistor.

11. The buffer of claim 10, wherein a drain saturation voltage of the first PMOS transistor in each branch is based on the current generated by the current source and a size of the diode-connected PMOS transistor.

12. The buffer of claim 9, further comprising:
a current source;
a diode-connected PMOS transistor having a source coupled to the supply voltage, a gate coupled to the current source and an output node, and a drain coupled to the current source and the output node; and
a resistor coupled between the output node and a node coupled to the current source, the gate of the diode-connected PMOS transistor, and the drain of the diode-connected PMOS transistor, wherein the second bias voltage is based on a current generated by the current source and a resistance of the resistor.

13. The buffer of claim 10, wherein a drain saturation voltage of the second PMOS transistor in each branch is based on the current generated by the current source and a size of the diode-connected PMOS transistor.

14. The buffer of claim 9, wherein a differential gain and a common mode gain between the respective output nodes is based on a transconductance of the first PMOS transistor in each branch, a transconductance of the second PMOS transistor in each branch, and an impedance of a load coupled to the output node.

15. A transmission circuit, comprising:
a mixer;
a plurality of segments each configured to be selectively deactivated, wherein each segment of the plurality of segments includes:
a driver amplifier (DA); and
a buffer to interface the mixer to the DA in the segment, wherein each buffer comprises a pair of p-channel metal-oxide-semiconductor (PMOS) transistors arranged in a common source and source follower configuration.

16. The transmission circuit of claim 15, wherein the pair of PMOS transistors in each segment comprise:
a first PMOS transistor having a source coupled to an output node, a gate coupled to an input voltage and to a first bias voltage, and a drain coupled to ground; and
a second PMOS transistor having a source coupled to a supply voltage, a gate coupled to an input voltage and to a second bias voltage, and a drain coupled to the output node.

17. The transmission circuit of claim 15, wherein the DA and the buffer have a different size in each of the plurality of segments.

18. The transmission circuit of claim 16, wherein only a segment, of the plurality of segments, with a smallest size that satisfies a power requirement is used at a talk time associated with the transmission circuit, and wherein a bias associated with each unused segment is pulled to ground at the talk time.

19. The transmission circuit of claim 15, further comprising:
a single segment that includes a DA and no buffer.

20. The transmission circuit of claim 18, wherein only the single segment with the DA and no buffer is used at a talk time associated with the circuit, and wherein a bias associated with the plurality of segments that include a DA and a buffer is pulled to ground at the talk time.
